(19) United States
(12) Patent Application Publication
(10) Pub. No.: US 2013/0273370 A1
(43) Pub. Date: Oct. 17, 2013

(54) ULTRATHIN NANOWIRE-BASED AND NANOSCALE HETEROSTRUCTURE-BASED THERMOELECTRIC CONVERSION STRUCTURES AND METHOD OF MAKING SAME

(71) Applicants: Yue Wu, West Lafayette, IN (US); Genqiang Zhang, Singapre (CN); Haiyu Fang, West Lafayette, IN (US); Haoran Yang, West Lafayette, IN (US)

(72) Inventors: Yue Wu, West Lafayette, IN (US); Genqiang Zhang, Singapre (CN); Haiyu Fang, West Lafayette, IN (US); Haoran Yang, West Lafayette, IN (US)

(21) Appl. No.: 13/891,914

(22) Filed: May 10, 2013

Related U.S. Application Data
(63) Continuation of application No. PCT/US2011/033798, filed on Apr. 25, 2011.
(60) Provisional application No. 61/327,192, filed on Apr. 23, 2010.
(60) Provisional application No. 61/327,199, filed on Apr. 23, 2010.

(51) Int. Cl. H01L 35/16

(52) U.S. Cl. CPC H01L 35/16
USPC 428/399; 428/401; 423/510; 423/509; 252/519.4

(57) ABSTRACT

A nanoscale heterostructure tellurium-based nanowire structure, including a rod-like tellurium nanowire structure and a metal telluride agglomeration connected to the rod-like nanowire structure. The metal telluride agglomeration may have an octahedral shape or a platelet shape. The agglomeration structures are selected from the group comprising lead telluride, cadmium telluride, bismuth telluride, and combinations thereof.

### PRIORITY

This application is a continuation-in-part of copending PCT/US2011/033798, filed on Apr. 25, 2011, which claimed priority to then-copending U.S. Provisional application Ser. Nos. 61/327,192 and 61/327,199, the entire contents of which are incorporated herein by reference, and also to copending U.S. Provisional Patent Application Ser. No. 61/645,132, filed on May 10, 2012, the entire contents of which are incorporated herein by reference.

### GRANT STATEMENT

The invention was made with government support under contract number CBET1048616 awarded by the National Science Foundation/Department of Energy Thermoelectric Partnership. The government has certain rights in the invention.

### TECHNICAL FIELD

The present disclosure generally relates to thermoelectric materials and, more particularly, to materials with nanowire-based and nanoscale heterostructure-based micro structures and processes of making same.

### BACKGROUND

In the modern world, production of thermal energy is a byproduct of almost every activity. Examples are operating internal combustion engines, lighting incandescent light bulbs, operating power plants, etc. Currently, most of the produced thermal energy is uncaptured and lost as waste heat. It would be beneficial to reclaim some or all of the unused thermal energy for transduction into a more useful form of energy.

Thermoelectric devices provide one way to convert thermal energy into electrical energy. A thermoelectric device positioned between a hot reservoir and a cold reservoir can use the thermal differential between these reservoirs to produce an electrical current. The reversal of this process, i.e., application of an electrical potential to a thermoelectric device, may be used to transfer heat from a first body to a second body, thereby cooling the first body. Referring to FIG. 16, a schematic of an application of prior art use of thermoelectric material is depicted.

One mechanism by which thermal energy is converted to electrical current is to as the Seebeck effect. The Seebeck effect can be explained as follows. A thermal gradient at a junction of two dissimilar materials, ΔT=T_{H}−T_{C} (see FIG. 4), can generate a voltage ΔV due to the Seebeck effect. The generated voltage is governed by

S=ΔV/ΔT (1),

where S is the Seebeck coefficient, ΔV is the generated voltage, and ΔT is the thermal gradient. Whether the Seebeck coefficient is a positive or negative number depends on the charge sign of the carriers, i.e., whether the carriers are holes or electrons. The higher the Seebeck coefficient, the higher voltage ΔV generated for the same thermal gradient ΔT.

Figure of Merit is one way to measure the efficiency of the thermoelectric material and structure. Figure of Merit is denoted as ZT and is expressed as

ZT=S²σT/κ (2),

where S is the Seebeck coefficient, σ is the electrical conductivity, κ is thermal conductivity, and T is the temperature. As follows from equation (2), a high figure of merit correlates to a low thermal conductivity and/or a high electrical conductivity. Low thermal conductivity slows heat transfer from the hot body to the cold body. The high electrical conductivity reduces electrical power losses due to electrical resistance.

Different structures have been investigated by others in the prior art to improve the Figure of Merit for different thermoelectric materials. Examples of thermoelectric materials characterized by high Figures of merit include bismuth telluride (Bi₂Te₃), and lead telluride (PbTe). However, as thermal conductivity and electrical conductivity are inherently limited, manipulation of these properties can only improve ZT by a limited amount.

Thus, there is a need to provide material selection, structure and method of making same that improves efficiency of thermoelectric conversion. The present disclosure addresses this need.

### SUMMARY

According to one aspect of the present disclosure, an ultrathin tellurium nanowire structure is disclosed. The nanowire structure includes a rod-like crystalline structure of tellurium, wherein the crystalline structure is defined by diameters of between about 5-6 nm.

According to another aspect of the present disclosure, an ultrathin tellurium-based nanowire structure is disclosed. The nanowire structure includes a rod-like crystalline structure of one of lead telluride and bismuth telluride, wherein an ultrathin tellurium nanowire structure is used as a precursor to generate the rod-like crystalline structure.

According to another aspect of the present disclosure, a nanoscale heterostructure tellurium-based nanowire structure is disclosed. The nanowire structure includes a dumbbell-like crystalline heterostructure having a center rod-like portion and one octahedral structure connected to each end of each of the center rod-like portions, wherein the center rod-like portion is a tellurium-based nanowire structure and the octahedral structures are one of lead telluride, cadmium telluride, and bismuth telluride.

### BRIEF DESCRIPTION OF DRAWINGS

FIGS. 1A and 1B are transmission electron microscopy (TEM) images of ultrathin tellurium nanowire structures with average diameters of about 5.5±0.5 nm depicted at different scales (A at 200 nm and B at 10 nm).

FIGS. 2A and 2B are TEM images of ultrathin lead telluride nanowire structures at different scales (A at 100 nm and B at 20 nm).

FIGS. 2C and 2D are TEM images of ultrathin bismuth telluride nanowire structures after injecting lead acetate and bismuth nitrate pentahydrate precursor solution into a tellurium nanowire solution at different scales (C at 100 nm and D at 20 nm).

FIG. 3 is X-ray diffraction patterns of tellurium, lead telluride and bismuth telluride nanowire structures.

FIGS. 4A and 4B are TEM images of tellurium nanowire structures with diameters of about 20 nm and lengths ranging from 1.2 to 1.5 micrometers depicted at different magnifications (A at 200 nm and B at 20 nm).

FIG. 5 is an X-ray diffraction pattern of the tellurium nanowire structures.

FIGS. 6A and 6B are TEM images of tellurium-lead telluride dumbbell-like heterostructure nanowire structures at different magnifications (A at 200 nm and B at 50 nm).

FIG. 7 is an X-ray diffraction pattern of the synthesized tellurium-lead telluride dumbbell-like heterostructure nanowire structures.

FIGS. 8A and 8B are TEM images of cadmium telluride-lead telluride dumbbell-like heterostructure nanowire structures at different magnifications (A at 500 nm and B at 100 nm).

FIG. 9 is an X-ray diffraction pattern of cadmium telluride-lead telluride dumbbell-like heterostructure nanowire structures.

FIGS. 10A and 10B are TEM images of bismuth telluride-lead telluride dumbbell-like heterostructure nanowire structure at different magnifications (A at 500 nm and B at 200 nm).

FIG. 11 is an X-ray diffraction pattern of bismuth telluride-lead telluride dumbbell-like heterostructure nanowire structures.

FIG. 12 is a plot of conductivity vs. temperature for lead telluride nanowire bulk sample compressed by spark plasma sintering.

FIG. 13 is a plot of Seebeck coefficient for lead telluride nanowire bulk sample compressed by plasma sintering.

FIG. 14 is a plot of Scaled amplitude vs. frequency at room temperature for lead telluride nanowire bulk sample compressed by spark plasma sintering.

FIG. 15 is a plot of thermoelectric figure of merit (ZT) vs. temperature for various samples.

FIG. 16 is a schematic of an application of PRIOR ART use of thermoelectric material.

FIG. 17 is a high resolution TEM image of a tellurium nanowire.

FIG. 18 is a side view high resolution TEM image of a Bi₂Te₃ platelet.

FIG. 19 is an enlarged plan view high resolution TEM image of the Bi₂Te₃ platelet of FIG. 18.

FIG. 20 is a graph of the electrical conductivity of a Te—Bi₂Te₃ nanowire composite material.

FIG. 21 is a graph of the Seebeck coefficient of a Te—Bi₂Te₃ nanowire composite material.

FIG. 22 is a graph of the thermal conductivity of a Te—Bi₂Te₃ nanowire composite material.

FIG. 23 is a graph of the ZT coefficient of a Te—Bi₂Te₃ nanowire composite material.

FIG. 24 is TEM photomicrograph of the Te nanowires of FIG. 17.

FIG. 25 is an enlarged TEM photomicrograph of the Te nanowires of FIG. 24.

FIG. 26 is TEM photomicrograph of the Te—Bi₂Te₃ nanowire composite material.

FIG. 27 is an enlarged TEM photomicrograph of the Te—Bi₂Te₃ nanowire composite material of FIG. 26.

### DETAILED DESCRIPTION

For the purposes of promoting an understanding of the principles of the present disclosure, reference will now be made to the embodiments illustrated in the drawings and described in the following written specification. It is understood that no limitation to the scope of the present disclosure is thereby intended. It is further understood that the present disclosure includes any alterations and modifications to the illustrated embodiments and includes further applications as would normally occur to one of ordinary skill in the art to which this disclosure pertains.

The present disclosure provides novel approaches to generate novel ultrathin nanowire-based structures as well as nanoscale heterostructure-based structures for use as material to be used in thermoelectric conversion. First, a novel process is described to generate a novel ultrathin nanowire structure. Second, a novel process is described to generate novel nanoscale heterostructure-based structures.

### Ultrathin Nanowire-Based Structures

The present disclosure provides an efficient process for synthesis of ultrathin lead telluride (PbTe) and bismuth telluride (Bi₂Te₃) nanowire structures 10. The process described generates novel nanowire structures 10 with diameters of about or less than 10 nm. The process includes utilizing ultrathin tellurium (Te) nanowire structures 10 as in-situ templates. Phase transfer from Te to PbTe or to BiₓTe₁₋ₓ is accomplished through injection of lead (Pb) or bismuth (Bi) precursor solutions to a solution containing Te nanowire.

The synthesized PbTe and Bi₂Te₃ ultrathin nanowire structures 10 are fabricated through a two-step process. First, the Te nanowire structures 10 are synthesized to be used as in-situ templates.

### Synthesis of Ultrathin Te Nanowire Structures

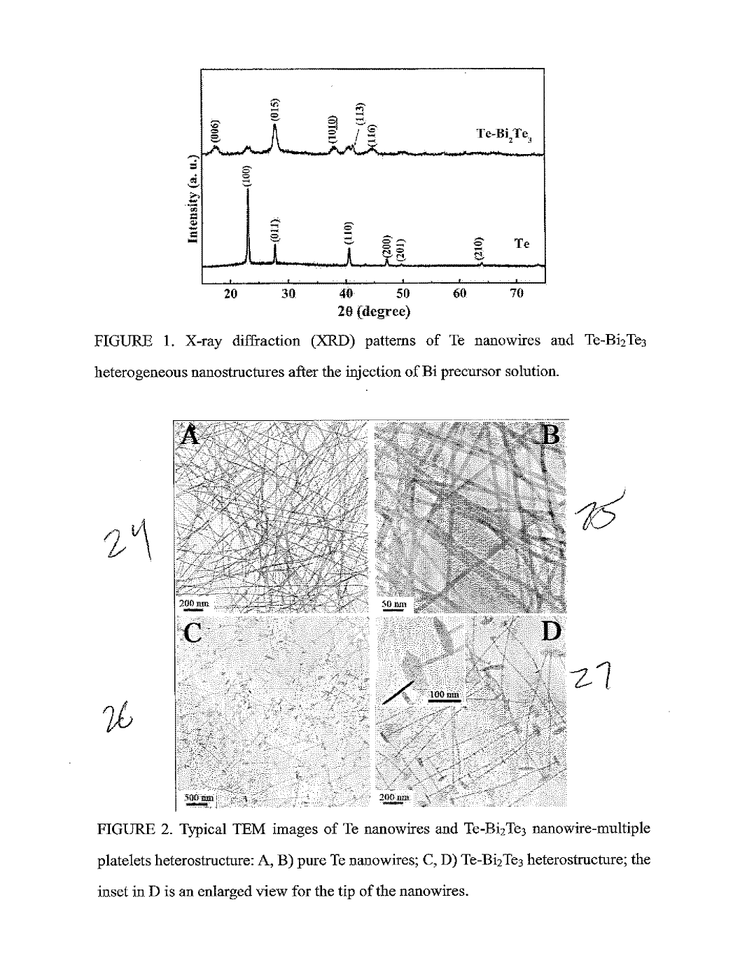

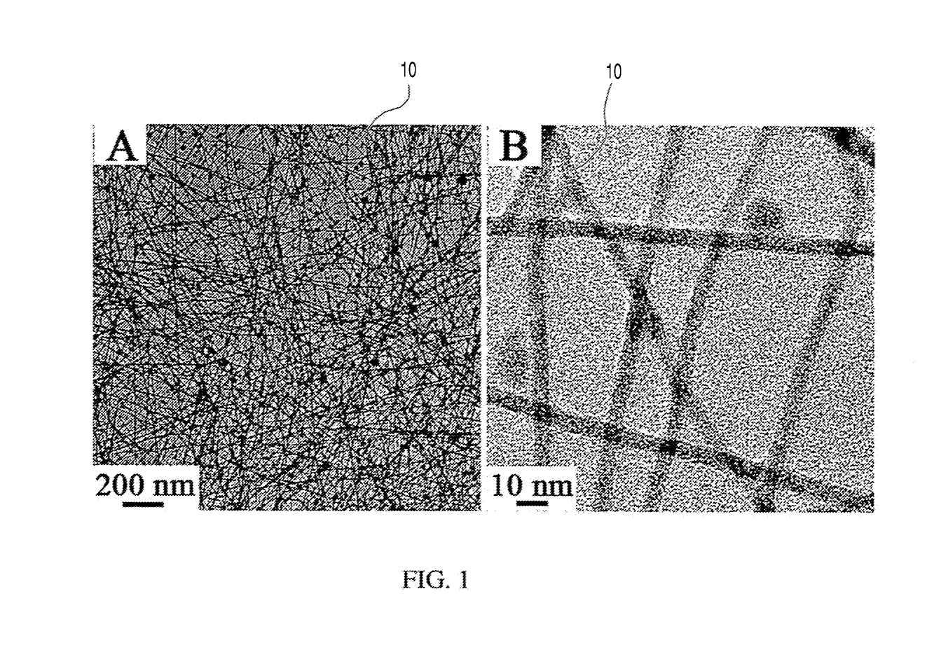

Ina typical synthesis, a volume of ethylene glycol (CH₂OHCH₂OH), e.g., 10 ml, an amount of polyvinylpyrrolidone (PVP), e.g., 0.1-1 g, an amount of an alkali (sodium hydroxide (NaOH) or potassium hydroxide (KOH), e.g., 0.2-0.8 g, and an amount of tellurium dioxide (TeO₂) or tellurite salts (sodium tellurite (Na₂TeO₃), or potassium tellurite (K₂TeO₃), e.g., 0.2-2 mmol, are dissolved in ethylene glycol by heating to form a transparent/translucent solution. Next, an amount of hydrazine hydrate (H₂NNH₂.H20) solution, e.g., 0.2-1 ml, is added into the as-prepared solution at 100-180° C. The concentration of hydrazine is typically between 24-100%, After about 20 minutes, ultrathin Te nanowire structures 10 with average diameters of 5.5±0.5 nm and lengths up to several micrometers are obtained. Referring to FIGS. 1A and 1B transmission electron microscopy (TEM) images of ultrathin tellurium nanowire crystalline structures 10 with average diameters of about 5.5±0.5 nm are depicted at different scales (A at 200 nm and B at 10 nm)

### Synthesis of Ultrathin Metal Telluride Nanowire Structures

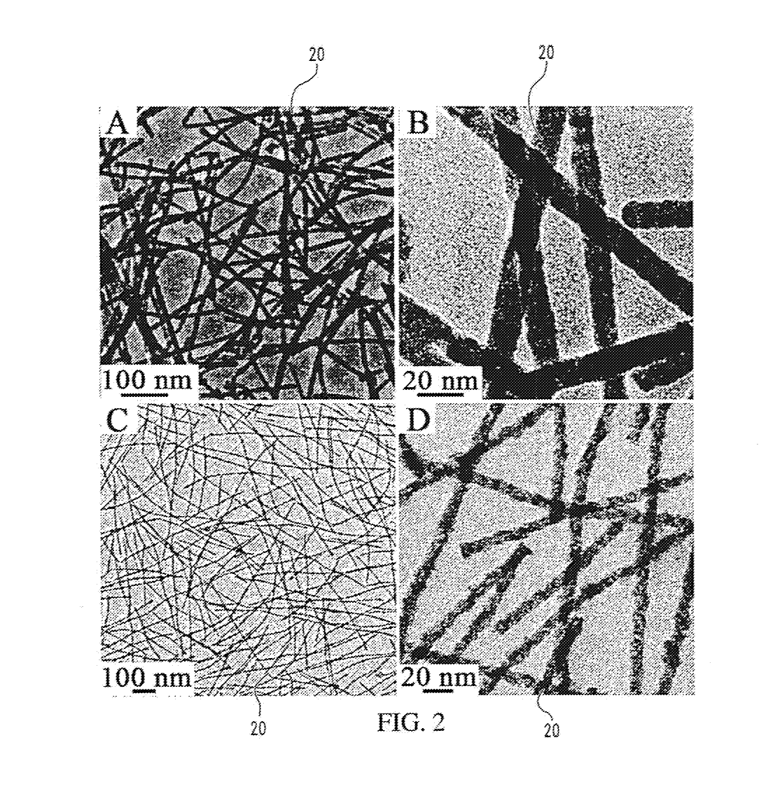

Using the synthesized ultrathin Te nanowire structures 10 as in-situ templates, metal telluride nanowire structures 20 may be produced by injecting associated metal precursors into the solution containing Te nanowire structures 10. The PbTe nanowire crystalline structures 20 with diameters of 9.5±0.5 nm and BiₓTe₁₋ₓ nanowire crystalline structures 20 with diameters of 7.5±0.5 nm can be obtained by injecting lead acetate tri-hydrate (Pb(CH,COO)2.3H2O) and bismuth nitrate penta-hydrate (Bi(N0₃₎₃.5H2O) in ethylene glycol precursor solution, respectively and allowing the solution to react for about 30 minutes. The quantity of the injected metal precursor is calculated according to the molar ratio of elements in corresponding compounds. Referring to FIGS. 2A and 2B, TEM images of ultrathin lead telluride nanowire structures 20 at different scales (A at 100 nm and B at 20 nm) are depicted. Referring to FIGS. 2C and 2D, TEM images of ultrathin bismuth telluride nanowire structures 20 after injecting lead acetate and bismuth nitrate pentahydrate precursor solution into a tellurium nanowire solution at different scales (C at 100 nm and D at 20 nm) are depicted.

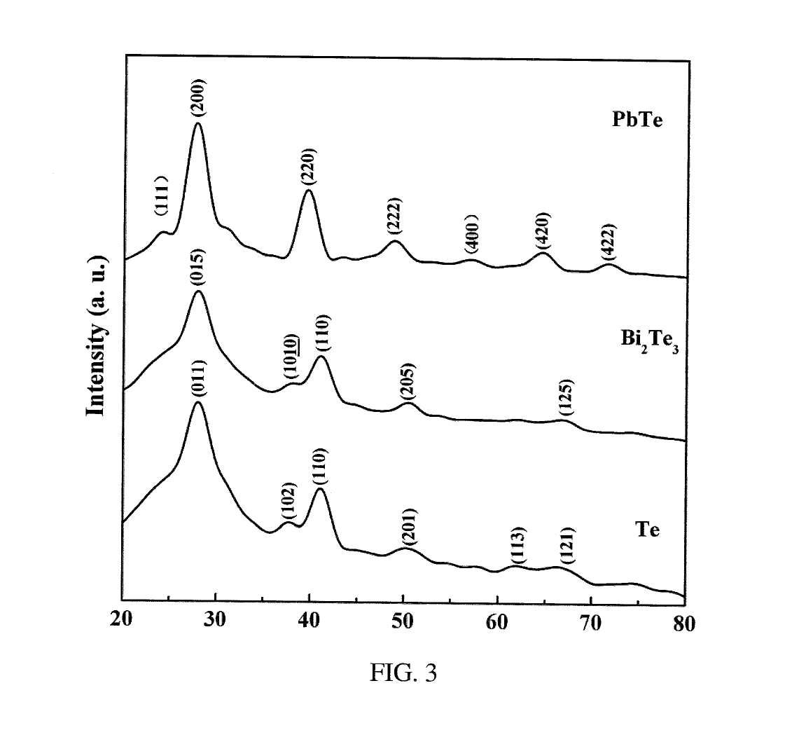

To verify the phase transfer from Te to PbTe or Bi₂Te₃ nanowire structures 20, X-ray diffraction patterns of these three materials were obtained. Referring to FIG. 3, X-ray diffraction patterns of tellurium, lead telluride and bismuth telluride nanowire structures 20 are depicted. As can be seen in FIG. 3, the nanowire structures 20 can be indexed to pure Te, PbTe and Bi₂Te₃, respectively, indicating the formation of PbTe and Bi₂Te₃ after the injection of the Pb or Bi precursor solution.

PbTe and Bi₂Te₃ are well suited candidates for thermoelectric conversion at temperatures of about room temperature and about 500° K, respectively. By fabricating novel nanowire structures 10, 20 with diameters less than 10 nm, the thermal conductivity can be significantly reduced to enhance the thermoelectric figure of merits by increasing the Seebeck coefficient. It is understood that the solution phase method, as described above, is easily scalable and reproducible for large-scale deployment of thermoelectric conversion devices.

The synthesized nanowire structures 20 are uniform and crystalline with diameters less than 10 nm (e.g., PbTe having diameters of about 9.5±0.5 nm; and Bi₂Te₃ having diameters of about 7.5±0.5 nm) and lengths up to several micrometers. In addition, both PbTe and Bi₂Te₃ nanowire structures 20 possess rough surfaces. These properties contribute to reduce the thermal conductivity of these materials as compared to corresponding bulk material. Also, the exact formation of the PbTe and Bi₂Te₃ nanowire structures 20 can be controlled by adjusting the molar ratio between the Pb or Bi precursor and TeO₂. This feature may help to determine the most efficient material systems for the application of thermoelectric devices. It is understood that the disclosed process may also be used to synthesize other metal telluride nanowire structures by simply adjusting the precursor solutions.

### Synthesis of Nanoscale Heterostructure-Based Structures

The present disclosure describes process steps resulting in synthesis of novel nanoscale heterostructure-based structures suitable for thermoelectric conversion. The process describes the use of an ethylene glycol based solution for synthesizing three novel dumbbell-like nanowire heterostructures 30. These heterostructures 30 are based on tellurium-lead telluride (Te—PbTe), cadmium telluride-lead telluride (CdTe—PbTe) and bismuth telluride-lead telluride (Bi₂Te₃—PbTe) compositions. First, well-defined Te nanowire structures 10 with diameters of about 20 run are developed. Thereafter, a Pb precursor solution is injected into the solution containing Te nanowire structures 10. As a result, PbTe octahedral structures are selectively grown at both ends of the Te nanowire structures to form Te—PbTe dumbbell-like structures 30. In order to obtain CdTe—PbTe and Bi2Te3-PbTe dumbbell-like structure 30, a cadmium (Cd) precursor or a bismuth (Bi) precursor solution is injected to the Te—PbTe heterostructure nanowire 10 solution, respectively. The center Te portion reacts with the reduced Cd or Bi atoms to form CdTe or Bi2Te3 nanowire structures 20, and then the CdTe—PbTe and Bi2Te3-PbTe part can be obtained.

### Te Nanowire Synthesis Structure

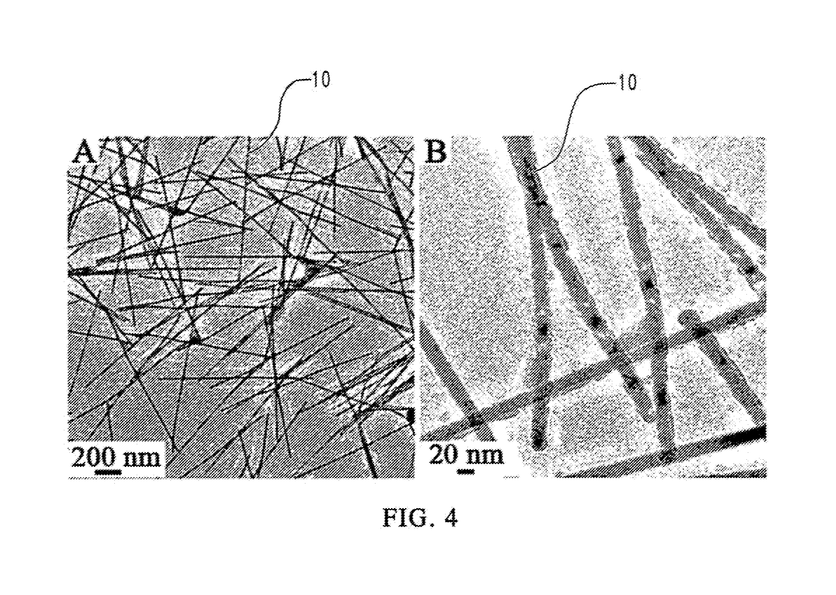

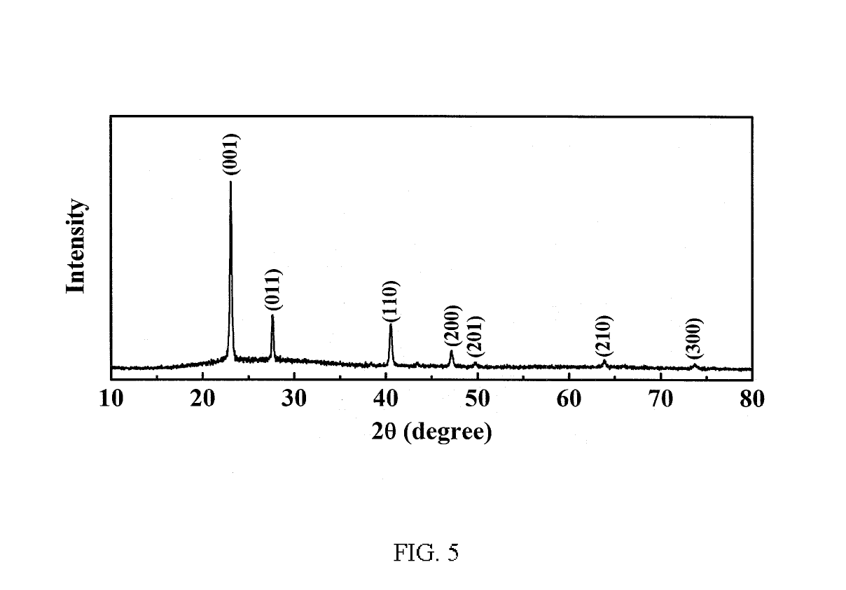

The process for synthesizing Te nanowire structures 20 is similar to the process of synthesizing ultrathin nanowire structures 10, described above. However, one difference is that the end of the nanowire synthesis process, after adding the hydrazine hydrate solution at I 00-1SO″C, the resulting solution is allowed to rest for about 20 minutes to one hour. The Te nanowire structures 20 obtained have average diameters of about 20±2 urn and lengths ranging from 1.2 to 1.5 micrometers. Referring to FIGS. 4A and 4B, TEM images of tellurium nanowire structures 20 with diameters of about 20 nm and lengths ranging from about 1.2 to about 1.5 micrometers are depicted at different magnifications (A at 200 nm and B at 20 nm). Also, referring to FIG. 5, an X-ray diffraction pattern of the tellurium nanowire structures 20 is provided. The X-ray diffraction pattern confirms the formation of pure hexagonal Te phase, as depicted in FIG. 5, which can be indexed according to Joint Committee on Powder Diffraction Standards (JCPDS) No. 79-0736. As depicted, the well-defined Te nanowire structures 20 can be used as the in-situ templates for the growth of agglomerations at either end to define dumbbell-like heterostructure nanowire structures 30.

### Synthesis of Dumbbell-Like Heterostructure Nanowire Structures

To generate Te—PbTe heterostructure nanowire structures 30, a Pb precursor solution is prepared by dissolving Pb(CH₃COO)₂3H₂O or Pb(NO₃)₂3H₂O into 1-3 ml ethylene glycol. The molar ratio between Pb(CH₃COO)₂3H₂O or Pb(NO₃)3H₂O and TeO₂, for the synthesis of Te nanowire structures is preferably less than 1. To synthesize Te—PbTe dumbbell-like heterostructure nanowire structures 30, the Pb precursor solution is injected to the Te nanowire solution at 100-180° C., followed by the addition of another 0.2-1 ml hydrazine solution with the concentration of 24-80%. After about 20 minutes, the Te—PbTe dumbbell-like heterostructure nanowire structures 30 can be obtained, with PbTe agglomerations positioned at either end of the Te nanowire.

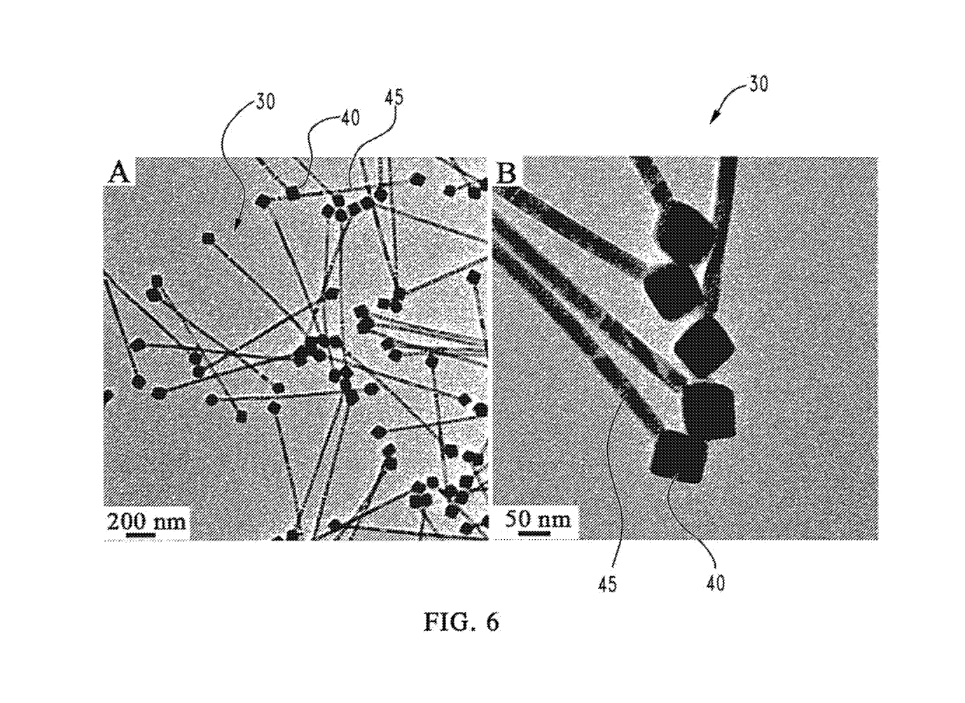

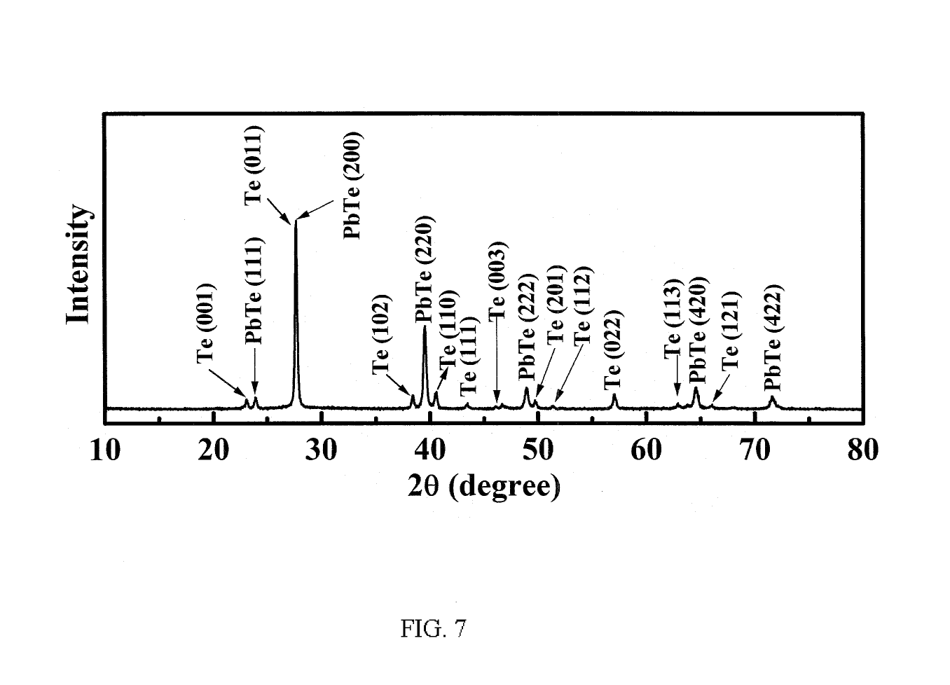

Referring to FIGS. 6A and 6B are TEM images of tellurium-lead telluride dumbbell-like heterostructure nanowire structures 30 at different magnifications (A at 200 nm and B at 50 nm) are depicted. As can be seen, the dumbbell-like structures 30 include Te nanowire structures 20 with two PbTe octahedral structures 40 selectively grown at both ends of the nanowire structures 20. The diameter and length of the Te nanowire 30 are about the same as the synthesized Te nanowire structures 20 and the edge length of PbTe octahedral structures 40 are about 65 nm as estimated from the TEM images. Referring to FIG. 7 an X-ray diffraction pattern of the synthesized tellurium-lead telluride dumbbell-like heterostructure nanowire structures is depicted. The X-ray diffraction pattern depicted in FIG. 7 can be readily indexed to hexagonal Te phase and cubic PbTe phase according to the JCPDS No. 79-0736 and 78-1905, respectively.

The synthesized Te—PbTe dumbbell-like structures 30 can be further converted to cadmium telluride-lead telluride (CdTc—PbTe) and bismuth telluride-lead telluride (BiₓTe₁₋ₓ—PbTe) dumbbell-like heterostructure nanowire structures 30 by selectively reacting the center Te nanowire portion with cadmium (Cd) or Bi precursor. For the synthesis of CdTe—PbTe dumbbell-like heterostructure nanowire structures 30, a Cd precursor solution can be used. The Cd precursor solution can be prepared by dissolving cadmium chloride (CdCl₂) or cadmium nitrate (Cd(N0₃)) or cadmium acetate (Cd(Ac)₂) into 1-3 ml ethylene glycol. The Cd precursor can then be injected into the solution containing the Te—PbTc dumbbell-like heterostructure nanowire structures 30. The molar ratio between the Cd and Te is about as 1:1 and the quantity can be calculated by subtracting those reacted with Pb precursors with the total Te precursor. For the synthesis of BiₓTe₁₋ₓ—PbTe dumbbell-like heterostructure nanowire structures 30, the Bi precursor solution prepared by dissolving BiCl₃ or Bi(N0₃)₂ or Bi(CH₃COO)₃ into 1-3 ml ethylene glycol.

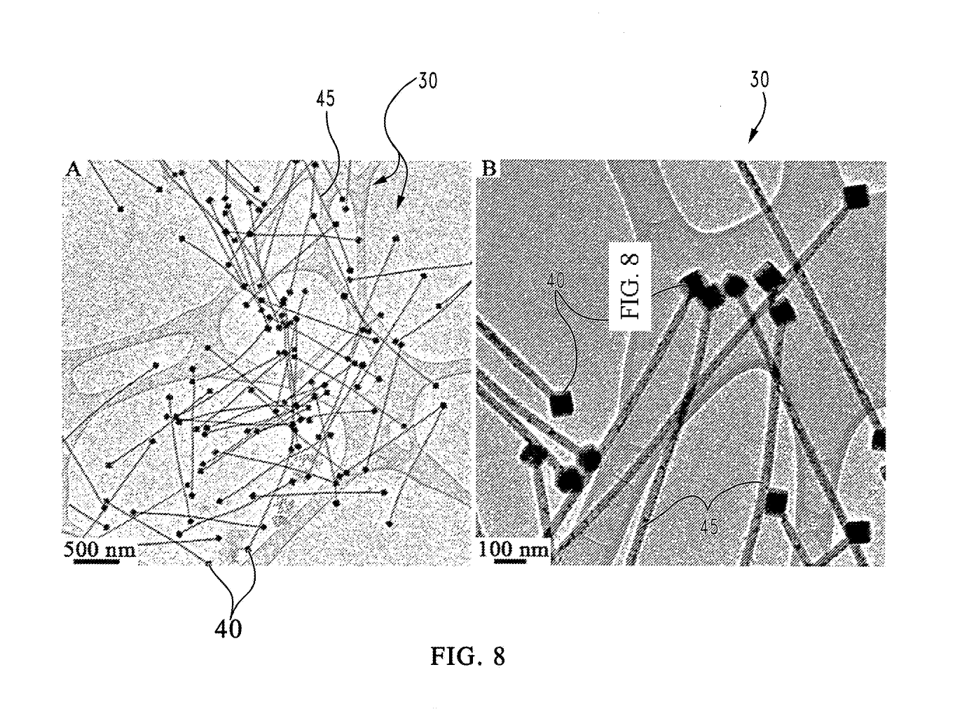

The Bi precursor can then be injected into the solution containing Te—PbTe dumbbell-like heterostructure nanowire structures 30. The x content in the BiₓTe₁₋ₓ Te₁₋ₓ can be controlled by adjusting the quantity of the Bi precursor when preparing the Bi precursor solution. Referring to FIGS. 8A and 8B, TEM images of cadmium telluride-lead telluride dumbbell-like heterostructure nanowire structures 30 at different magnifications (A at 500 nm and B at 100 nm) are provided.

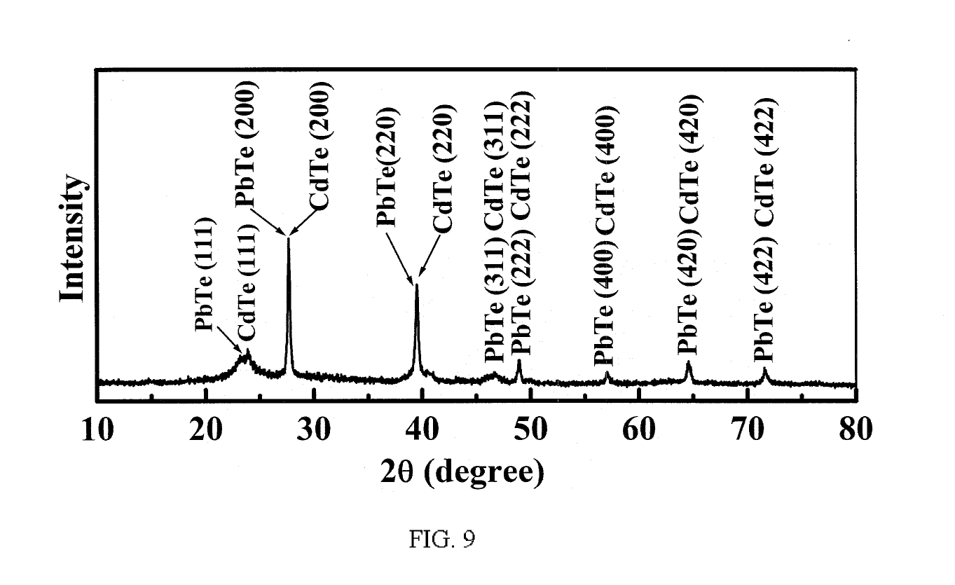

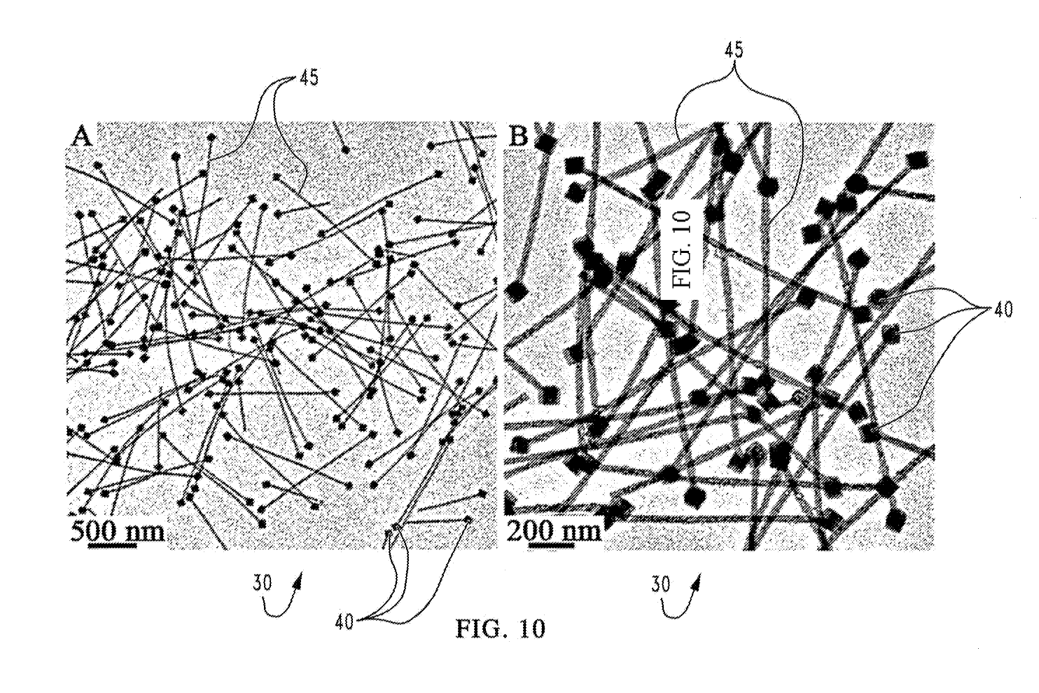

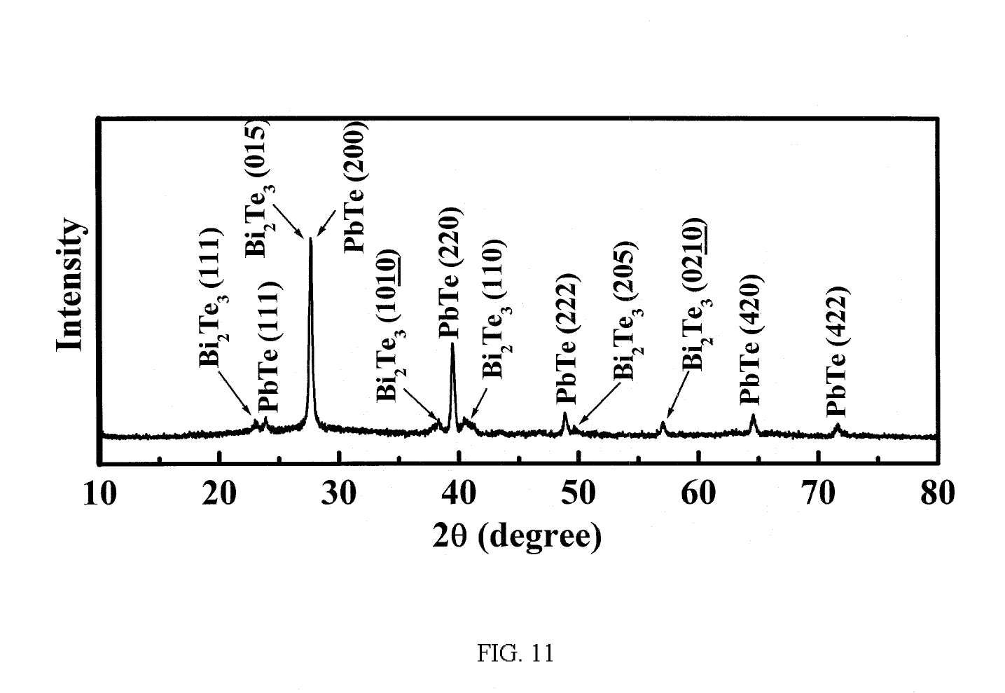

The morphology of the resulting products is quite similar to that of Te—PbTe dumbbell-like structures except that the diameter of the center CdTc part is about 30 nm, which is slightly larger than that of center Te part in the Te—PbTe dumbbell-like structure 30. In addition, the XRD pattern of the CdTe—PbTe resulting products is quite different from that of Te—PbTe dumbbell structure 30. Referring to FIG. 9 an X-ray diffraction pattern of cadmium telluride-lead telluride dumbbell-like heterostructure nanowire structures 30 is provided. The XRD can be indexed to cubic CdTe and cubic PbTe phase according to the JCPDS card No. 75-2083 and 78-1905, indicating the formation of CdTe center part. Referring to FIGS. 10A and 10B, TEM images of bismuth telluride-lead telluride dumbbell-like heterostructure nanowire structure 30 at different magnifications (A at 500 nm and B at 200 nm) are provided. These structures are similar to that of the CdTe—PbTe structure. Referring to FIG. 11, however, an X-ray diffraction pattern of bismuth telluride-lead telluride dumbbell-like heterostructure nanowire structures 30 is depicted, which can be readily indexed to hexagonal PbTe phase and cubic PbTe phase according to the JCPDS card No. 72-2036 and 78-1905, which indicates the difference between CdTe—PbTe 40 and Bi₂Te₃—PbTe 40 and demonstrates the formation Bi₂Te₃ center portion 45.

The PbTe and Bi₂Te₃ are well-suited for thermoelectric conversion at temperature close to near room temperature and 500 K, respectively. By fabricating these novel nanoscale heterostructure-based nanowire structures 30 with the above-identified materials, both the thermal conductivity and the Seebeck coefficient, particularly the former, can be significantly optimized to enhance the thermoelectric Figure of Merit. The above-referenced solution phase synthesis is easily scalable and reproducible for large-scale deployment of thermoelectric conversion devices.

The thermal conductivity of the materials could be further reduced due to combination of the interface scattering effect and size confinement effect compared with the conventional nanowire structures. The teachings of the present disclosure can be extended to other nanowire heterostructure synthesis by changing the precursor solution to provide other tellurium-based thermoelectric materials.

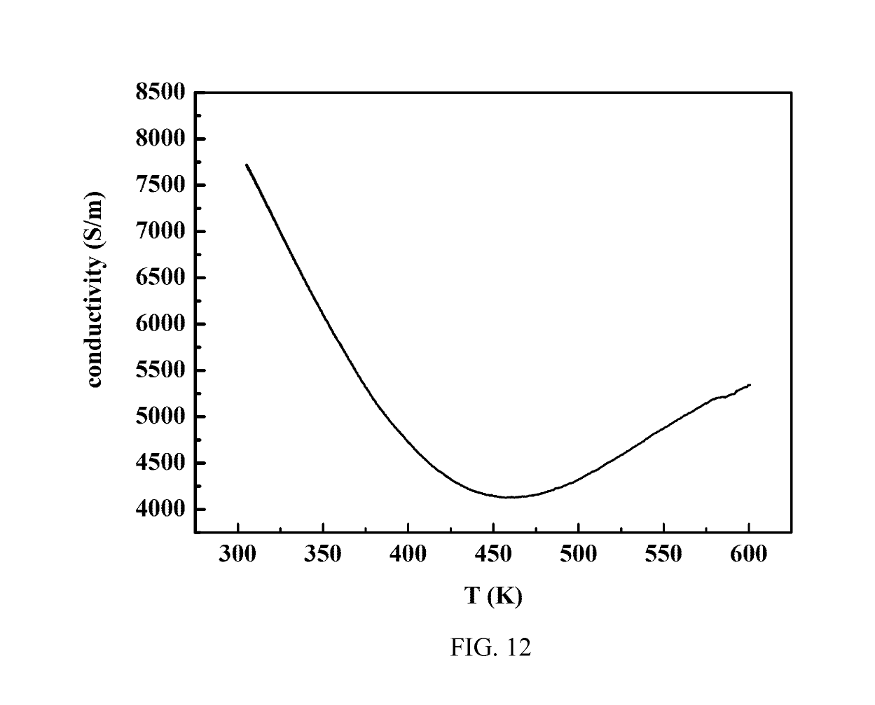

To demonstrate the improved efficiency of the synthesized thermoelectric structures as compared to bulk material, thermoelectric properties of PbTe was measured. Referring to FIG. 12, a plot of electrical conductivity vs. temperature for lead telluride nanowire bulk sample compressed by spark plasma sintering is depicted. As can be seen from FIG. 12, the electrical conductivity of the sample is about 7714 S/m at 300 K. The electrical conductivity first decreases with increases in temperature until about 460 K reaching a minimum value of 4126 S/m. The electrical conductivity then increases with increases in temperature. Compared with that of bulk sample, the electrical conductivity of the synthesized PbTe nanowire bulk sample is much lower, about one fourth of that of bulk sample.

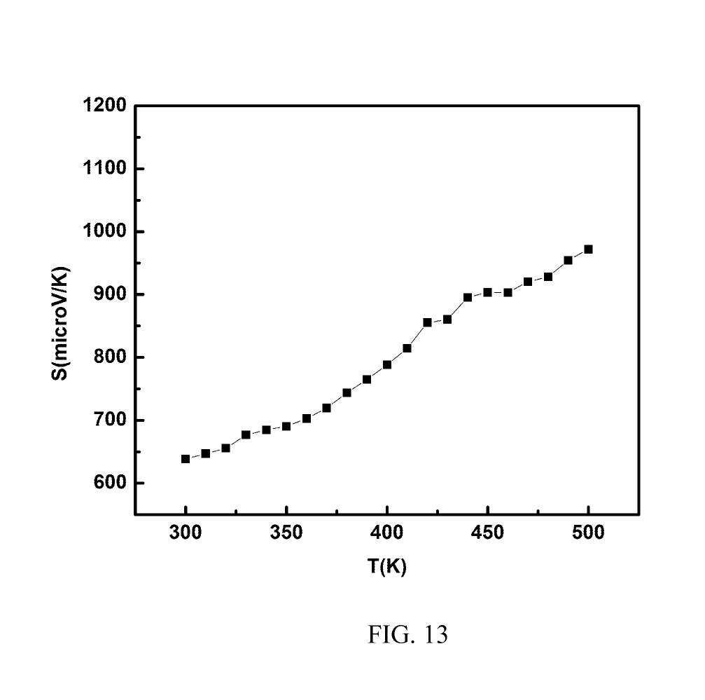

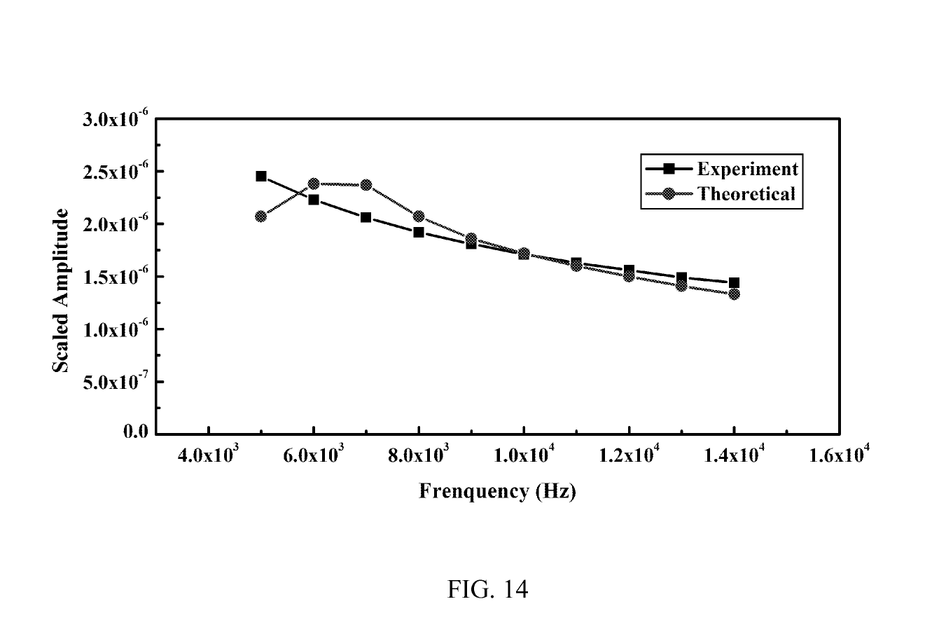

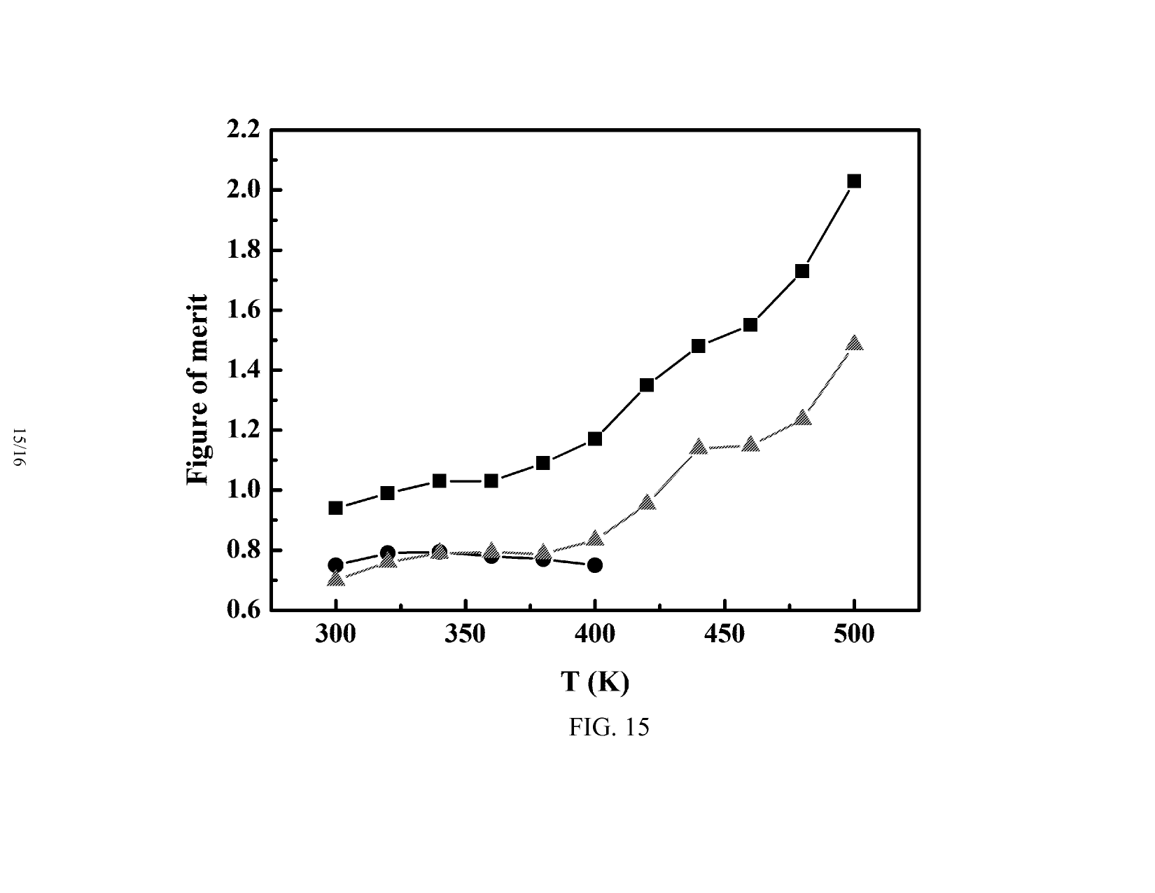

The Seebeck coefficient is largely enhanced compared with that of bulk sample, about 2 to 4 times higher than that of bulk sample. Referring to FIG. 13, a plot of Seebeck coefficient for lead telluride nanowire bulk sample compressed by plasma sintering is depicted. The thermal conductivity of the sample through a phonon acoustic based method was also measured. Referring to FIG. 14, a plot of Scaled amplitude vs. frequency at room temperature for lead telluride nanowire bulk sample compressed by spark plasma sintering is depicted. FIG. 14 depicts the curves of experimental and fitting data for PbTe nanowire bulk sample at room temperature, giving a total thermal conductivity value of about 1 Wₘ⁻¹K⁻¹ which is around 2 times lower than bulk or other data reported in the prior art. A series of figure of merit (ZT) values were calculated and plotted versus temperature. Referring to FIG. 15 a plot of thermoelectric Figure of Merit (ZT) vs. temperature is depicted for various samples. For the sample providing the best ZT, a ZT value of 2.03, was obtained which is higher as compared with previously reported values of ZT in the prior art.

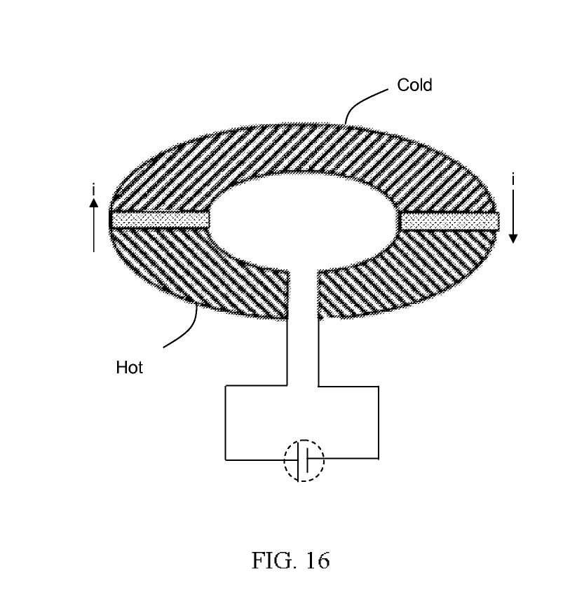

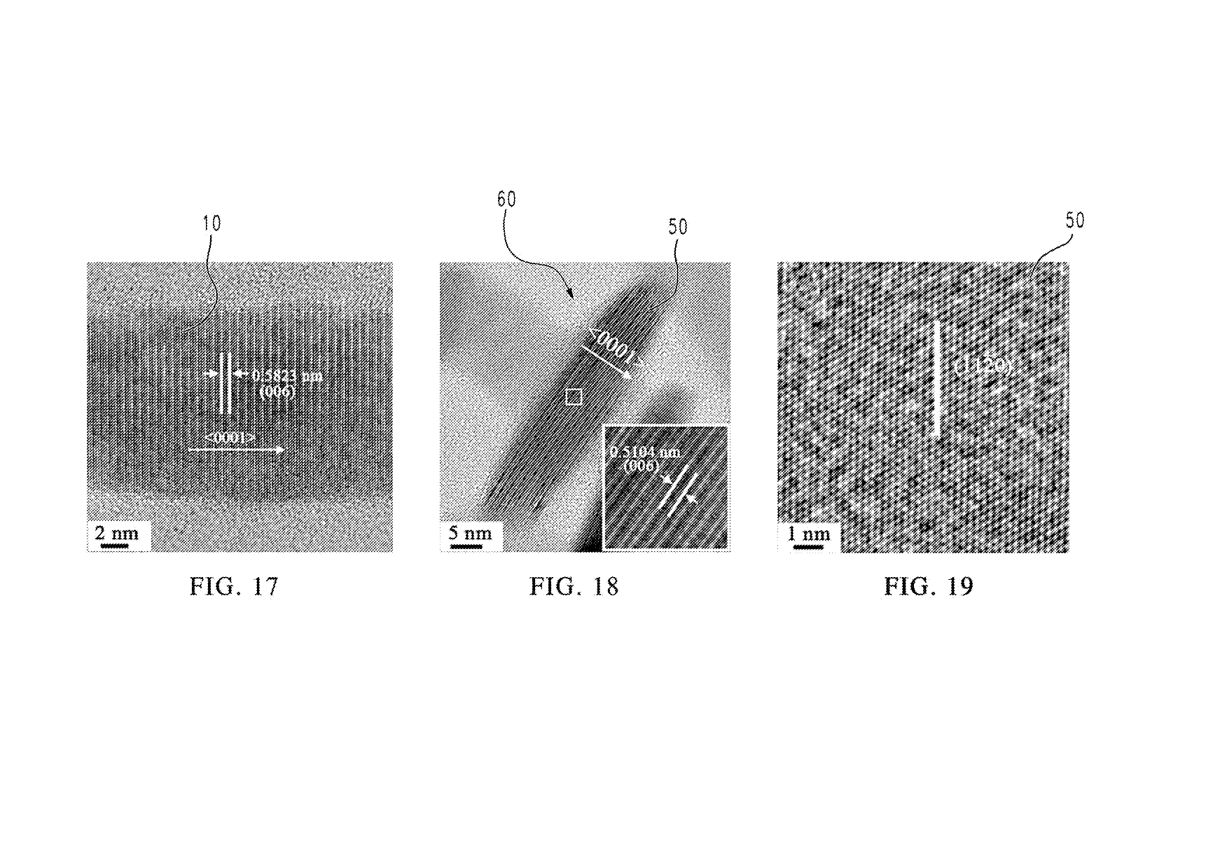

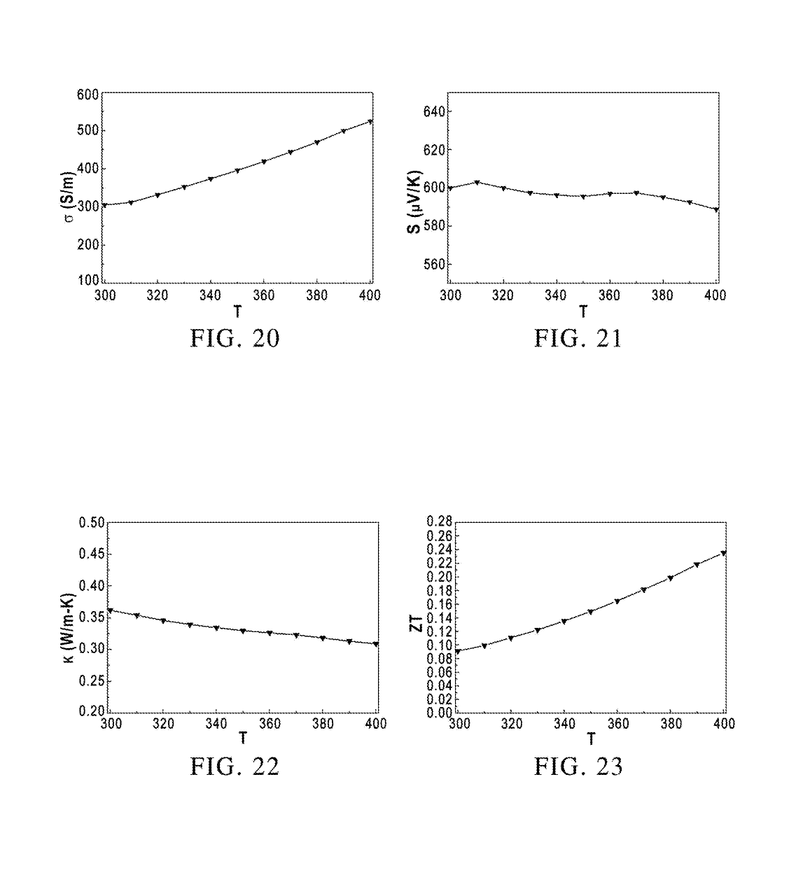

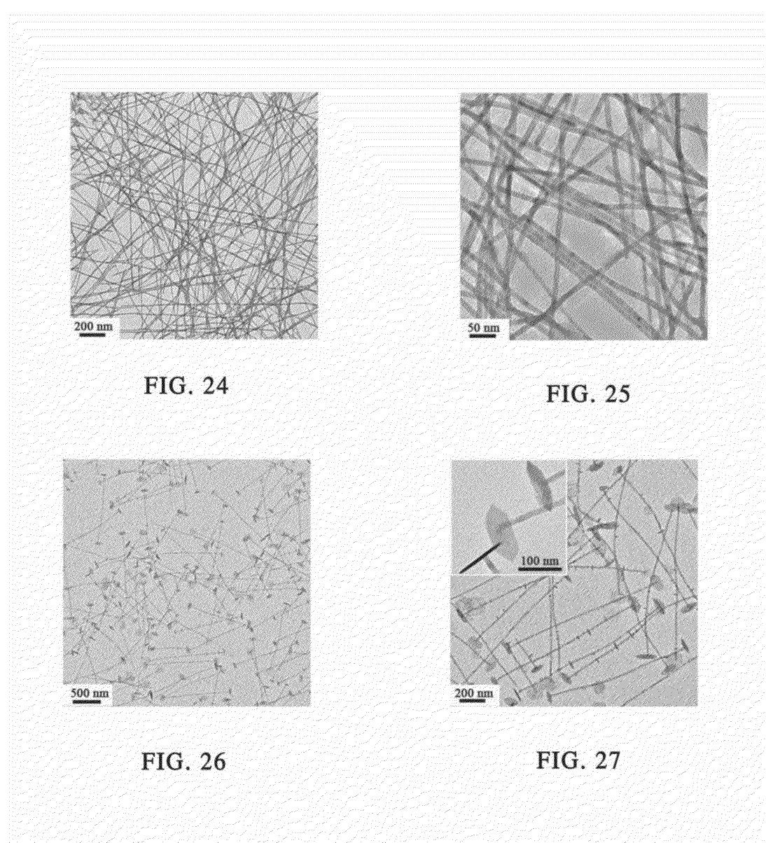

In one embodiment, as seen in FIGS. 17-27, a two-step solution phase synthesis and subsequent thermoelectric characterization of Te—Bi₂Te₃ nanowire-hexagonal platelets heterostructure 50 was accomplished. The Te—Bi₂Te₃ nanoparticles 50 were synthesized by a solvent phase reaction. The as-synthesized Te—Bi₂Te₃ nanoparticles were washed, separated from the solvent and dried to yield nanocrystalline Te—Bi₂Te₃ powder. Then hot-pressing was used to compress the powder into bulk material while preserving the nanosized structure. The final product can be directly used in a thermoelectric generator or in a thermoelectric refrigerator. The small scale or nanosize of the Te—Bi₂Te₃ nanowire-hexagonal platelets heterostructure 50 contributes a quantum confinement effect which improves the Seebeck coefficient S, and the grain boundaries in the heterostruture effectively block phonons, which reduces the thermal conductivity κ of the materials. These two cooperating effects give rise to enhanced ZT values, which indicate high thermoelectric device efficiency.

The electrical conductivity of the heterostructure nanowire composites 60 increases almost linearly from 3.051 S/cm at 300 K to 5.244 S/cm at 400 K. The electrical conductivity of our heterostructure nanowire composites is much higher than that of pure Te nanowires which is around 0.08 S/cm. The improved electrical conductivity compared with pure Te nanowires is likely derived from the heterostructure feature by epitaxial growth of highly conductive Bi₂Te₃ nanoplatelets 50 onto Te nanowires 10, which enhance the electron transfer after the hot pressing. In addition, a largely enhanced Seebeck coefficient is also achieved in this heterostructure, ranging from around 608 μV/K at 300 K to 588 μV/K at 400 K. The thermal conductivity is 0.365 Wm⁻¹K⁻¹ at 300 K and slightly decreases to 0.395 Wm⁻¹K⁻¹ at 400 K. The value of thermal conductivity observed in our heterostructure nanowire composites 60 is much lower than that of pure Te nanowires (2 Wm⁻¹K⁻¹) and is comparable to that of Te nanowire:PEDOT:PSS hybrid nanostructure (0.22-0.30 Wm⁻¹K⁻¹). The calculated ZT value is around 0.09 at 300 K and increases to around 0.24 at 400 K. The ZT value is largely enhanced compared with that of pure Te nanowires (0.0004) by constructing this novel nanowire-multiple nanoplatelets heterostructures 60 with a facile two-step solution phase routes.

The Te—Bi₂Te₃ nanowire-hexagonal platelet type heterostructure 60 can be used as templates to synthesize similar nanostructures but with variable materials components, which also can be used as thermoelectric materials, such as lead telluride-bismuth telluride, silver telluride-bismuth telluride, and the like.

Those skilled in the art will recognize that numerous modifications can be made to the specific implementations described above. Therefore, the following claims are not to be limited to the specific embodiments illustrated and described above. The claims, as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others.

1. An ultrathin tellurium nanowire structure, comprising:
a rod-like crystalline structure of tellurium, wherein the crystalline structure is defined by diameters of between 5-6 nm.

2. The ultrathin tellurium nanowire structure of claim 1, wherein the crystalline structure is prepared by a process comprising the steps of:
(a) mixing an amount of polyvinylpyrrolidone, an amount of an alkali, and an amount of one of tellurium dioxide and telluride salt to generate a first solution;
(b) dissolving the first solution in ethylene glycol to generate a second mixture;
(c) heating the second mixture; and
(d) mixing an amount of hydrazine hydrate with the second mixture to generate a third mixture containing the rod-like crystalline structure of tellurium.

3. The ultrathin tellurium nanowire structure of claim 2, wherein the amount of polyvinylpyrrolidone is about 0.1 to 1.0 g.

4. The ultrathin tellurium nanowire structure of claim 3, wherein the amount of alkali is about 0.2 to 0.8 g.

5. The ultrathin tellurium nanowire structure of claim 4, wherein the alkali is one of sodium hydroxide and potassium hydroxide.

6. The ultrathin tellurium nanowire structure of claim 5, wherein the tellurium salt is one of sodium tellurite, potassium tellurite, and tellurium dioxide.

7. The ultrathin tellurium nanowire structure of claim 6, wherein the second mixture is heated to about 100-180° C.

8. The ultrathin tellurium nanowire structure of claim 7, wherein the amount of hydrazine hydrate is about 0.2 to 1 ml.

9. An ultrathin tellurium-based nanowire structure, comprising:
a rod-like crystalline structure of one of lead telluride and bismuth telluride, wherein an ultrathin tellurium nanowire structure is used as a precursor to generate the rod-like crystalline structure.

10. The ultrathin tellurium-based nanowire structure of claim 9, wherein the lead telluride rod-like crystalline structure includes diameters between 9-10 nm and the bismuth telluride rod-like crystalline structures includes diameters between 7-8 nm.

11. The ultrathin tellurium-based nanowire structure of claim 10, wherein the precursor ultrathin nanowire includes diameters between 5-6 nm.

12. The ultrathin tellurium-based nanowire structure of claim 9, wherein a plurality of rod-like crystalline structures are sintered together to yield a densified macrostructure.

13. The ultrathin tellurium-based nanowire structure of claim 9, wherein the crystalline structure is prepared by a process comprising the step of:
injecting one of lead acetate tri-hydrate and bismuth nitrate penta-hydrate into an ethylene glycol precursor solution containing the ultrathin tellurium nanowire structures.

14. A nanoscale heterostructure tellurium-based nanowire structure, comprising:
a dumbbell-like crystalline heterostructure having a center rod-like portion; and
at least one octahedral structure connected to each end of each of the center rod-like portions;
wherein the center rod-like portion is a tellurium nanowire structure; and
wherein the octahedral structures are one of lead telluride, cadmium telluride, and bismuth telluride.

15. The nanoscale heterostructure tellurium-based nanowire structure of claim 14, wherein the center rod-like portion is defined by a diameter of about 20 nm.

16. The nanoscale heterostructure tellurium-based nanowire structure of claim 15, wherein edge length of the lead telluride is about 65 nm.

17. The nanoscale heterostructure tellurium-based nanowire structure of claim 16, wherein diameter of the cadmium telluride octahedral structure is about 30 nm.

18. The nanoscale heterostructure tellurium-based nanowire structure of claim 14, wherein the dumbbell-like crystalline structure is prepared by a process comprising:
(a) preparing a lead precursor solution; and
(b) injecting the lead precursor solution into an ethylene glycol precursor solution containing the tellurium-based nanowire structures.

19. The nanoscale heterostructure tellurium-based nanowire structure of claim 18, wherein the lead precursor is prepared by dissolving one of Pb(CH₃COO)₂3H₂O and Pb(N0₃)₂3H₂O into ethylene glycol.

20. The nanoscale heterostructure tellurium-based nanowire structure of claim 18, wherein the ethylene glycol precursor solution containing the tellurium-based nanowire structures is prepared by a process comprising the steps of:
(a) mixing an amount of polyvinylpyrrolidone, an amount of an alkali, and an amount of one of tellurium dioxide and telluride salt to generate a first solution;
(b) dissolving the first solution in ethylene glycol to generate a second mixture;
(c) heating the second mixture; and
(d) mixing an amount of hydrazine hydrate with the second mixture to generate the ethylene glycol precursor solution.

21. The nanoscale heterostructure tellurium-based nanowire structure of claim 20, wherein the molar ratio between one of Pb(CH3COO).3H₂0 and Pb(NO3)₂3H₂0 and tellurium dioxide is less than 1.

22. A densified body, comprising:
a grain boundary matrix; and
a plurality of Te—Bi₂Te₃ particles distributed throughout the grain boundary matrix.

23. The densified body of claim 22, wherein the respective Te—Bi₂Te₃ particles further comprise at least one Bi₂Te₃ platelet positioned on a Te nanowire.

24. The densified body of claim 23 wherein Bi₂Te₃ platelets define agglomerations at least one end of a Te nanowire.

25. A nanoscale heterostructure tellurium-based nanowire structure, comprising:
a rod-like tellurium nanowire structure; and
a metal telluride agglomeration connected to the rod-like nanowire structure.

26. The nanoscale heterostructure tellurium-based nanowire structure of claim 25 wherein the metal telluride agglomeration is selected from the group comprising lead telluride, cadmium telluride, and bismuth telluride.

27. The nanoscale heterostructure tellurium-based nanowire structure of claim 25 wherein the rod-like tellurium nanowire structure has a pair of oppositely disposed ends; and wherein the metal telluride agglomeration is an octahedral structure connected to each respective end of the rod-like tellurium nanowire structure.

28. The nanoscale heterostructure tellurium-based nanowire structure of claim 25 wherein the metal telluride agglomeration is a platelet.

29. The nanoscale heterostructure tellurium-based nanowire structure of claim 28 wherein the rod-like tellurium nanowire structure has at least one end; and wherein the metal telluride platelet is connected to the at least one end.
